(19) United States
(12) Patent Application Publication
(10) Pub. No.: US 2003/0217314 A1
(43) Pub. Date: Nov. 20, 2003

(54) Semiconductor memory device with data scramble circuit

(76) Inventors: Jong-Tai Park, Ichon-shi (KR); Sung-Ho Bae, Ichon-shi (KR)

Correspondence Address: Law Offices, Jacobson Holman, Professional Limited Liability Company, 400 Seventh Street, N.W., Washington, DC, 20004-2218, US

(21) Appl. No.: 10/330,020

(22) Filed: Dec. 27, 2002

(30) Foreign Application Priority Data
Apr. 4, 2002 (KR) 2002-18471

(51) Int. Cl. G11C 29/00

(52) U.S. Cl. 714/720

(57) ABSTRACT

A semiconductor memory device includes a first data scramble circuit, which is configured between a data input buffer and a memory cell block, for outputting data by inverting or maintaining a polarity of an input data in response to a data scramble control signal and a second data scramble circuit, which is configured between the memory cell block and a data output buffer, for outputting data by inverting or maintaining a polarity of an output data in response to a data scramble control signal.

### FIELD OF THE INVENTION

The present invention relates to a semiconductor memory device; and, more particularly, to a semiconductor memory device having a data scramble circuit therein.

### DESCRIPTION OF RELATED ART

As an integration degree of a semiconductor memory device rapidly increases, a number of memory cells over ten millions are integrated on one memory chip. As the number of memory cells increase, it takes a long time to test whether the memory cell is normal or fail. The memory cell test has to be performed by considering accuracy for an analysis result and reduction for a test time.

Generally, the memory cell array is raid out with an identical pattern. However, a specific memory cell block may be frequently raid out by being 180° rotated, so that data inputted through a specific input/output lines or a specific address range of the specific memory cell block may be incorrectly written to the memory cell. Namely, an inverted data polarity is written in the memory cell. When a fail related to the memory cell is generated, since it is very important that determines whether the fail is a high fail or a low fail to solve the fail, the incorrectly written data may cause a sever problem for a fail analysis.

In order to solve the above problem, a data scramble equation is programmed in advance to a semiconductor device. Therefore, if a data polarity inputted trough an input/output pin (DQ) is not identical to a data polarity written in a memory cell, a data having an opposite polarity is inputted to the DQ pin.

However, since the data scramble equation for each semiconductor memory device is not identical each other, the data scramble equation has to be reprogrammed every time for each semiconductor memory device. Also, there is a problem that an analysis equipment, in which the data scramble is not supported, cannot be used.

### SUMMARY OF THE INVENTION

It is, therefore, an object of the present invention to provide a semiconductor memory device having a data scramble circuit, which is applied to a fail analysis equipment not supporting a data scramble and is not necessary to reprogram a data scramble equation for each semiconductor memory device.

In accordance an aspect of the present invention, there is provided a semiconductor memory device comprising: a first data scramble circuit, which is configured between a data input buffer and a memory cell block, for outputting data by inverting or maintaining a polarity of an input data in response to a data scramble control signal; and a second data scramble circuit, which is configured between the memory cell block and a data output buffer, for outputting data by inverting or maintaining a polarity of an output data in response to a data scramble control signal.

### BRIEF DESCRIPTION OF THE DRAWINGS

The above and other objects and features of the instant invention will become apparent from the following description of preferred embodiments taken in conjunction with the accompanying drawings, in which:

FIG. 1 is a block diagram illustrating a write path in accordance with the preferred embodiment of the present invention;

FIG. 2 is a circuit diagram illustrating the data scramble circuit in FIG. 1; and

FIG. 3 is a block diagram illustrating a read path in a semiconductor memory device in accordance with the preferred embodiment of the present invention.

### DETAILED DESCRIPTION OF THE INVENTION

Hereinafter, a semiconductor memory device having a data scramble circuit according to the present invention will be described in detail referring to the accompanying drawings.

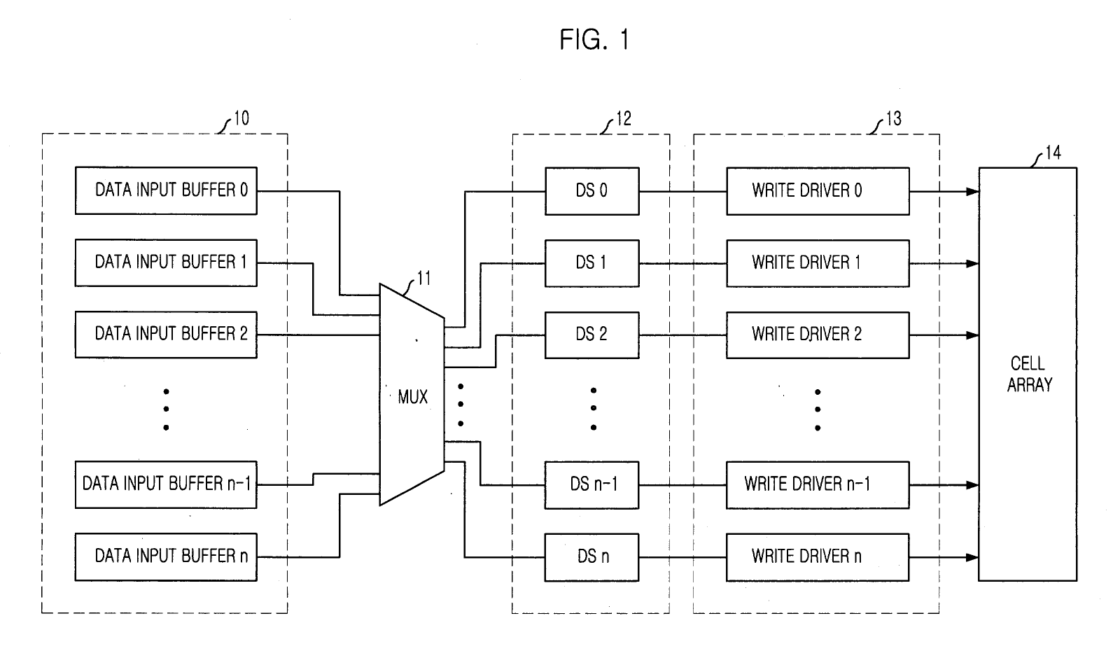

FIG. 1 is a block diagram illustrating a write path in accordance with the preferred embodiment of the present invention.

As shown, the write path includes a data input buffer block 10, a MUX 11, a data scramble block 12, a write driver block and a memory cell array block 14. The data input buffer block 10 transmits data provided from an external circuit to an internal circuit and the MUX 11 multiplexes an output of the data input buffer to each I/O line according to a data width. The data scramble block 12 scrambles data transmitted to each I/O line and the write driver block 13 drives bitlines of corresponding memory cell for writing scrambled data in the memory cell array block 14. Compared with the prior art, it is different that the data scramble circuit is inserted on each I/O line of the write path.

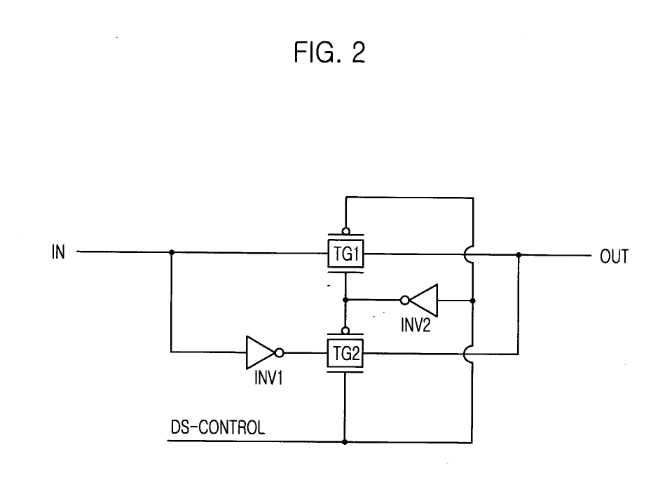

FIG. 2 is a circuit diagram illustrating the data scramble circuit in accordance with the preferred embodiment of the present invention.

As shown, the data scramble circuit includes a first transfer gate TG1 for selectively outputting an input data IN in response to a data scramble control signal DS-CONTROL and a second transfer gate TG2 for selectively outputting an inverted input data through a first inverter INV1 in response to the data scramble control signal DS-CONTROL. Since the first transfer gate TG1 and the second transfer gate TG2 receives the data scramble control signal DS-CONTROL having an opposite characteristic each other, one of the transfer gates is enabled by controlling the data scramble control signal DS-CONTROL. A second inverter INV2 is used to invert the data scramble control signal DS-CONTROL.

The data scramble control signal DS-CONTROL is activated at a specific input/output line or a specific address range and can be generated by decoding a row address or a column address.

After a design of the semiconductor memory device is completed, a specific memory cell or memory cell block, in which the data applied to a data input/output pin (DQ) is different from a data written in the memory cell, is defined.

If a corresponding input/output line is a normal input/output line, in which a data polarity is not inverted, the data scramble control signal DS-CONTROL applied to the data scramble circuit inserted in the corresponding input/output line is disabled with a logic ‘low’ level, so that the data, in which the data polarity is not inverted, is outputted through the first transfer gate TG1. On the other hand, if a corresponding input/output line is an abnormal input/output line, in which a data polarity is inverted, the data scramble control signal DS-CONTROL applied to the data scramble circuit inserted in the corresponding input/output line is enabled with a logic ‘high’ level, so that the data, in which the data polarity is inverted, is outputted through the second transfer gate TG2.

Accordingly, there are advantages that, even if the analysis equipment cannot support the data scramble, a fail analysis of the semiconductor memory can be easily carried out and it is not necessary to reprogram the data scramble equation for each semiconductor memory device.

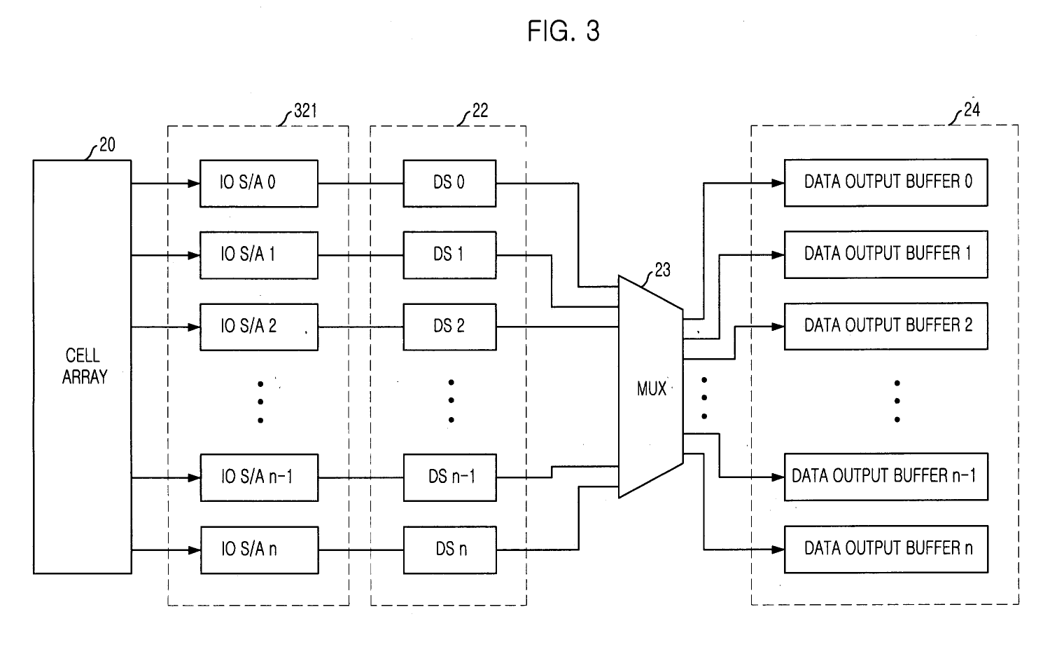

FIG. 3 is a block diagram illustrating a read path in a semiconductor memory device in accordance with the preferred embodiment of the present invention.

As shown, the read path includes a cell array block 20, an input/output sense amplification block 21, a data scramble block 22, a MUX 23 and a data output buffer 24. The sense amplification block 21 senses and amplifies a bitline of corresponding memory cell in the cell array block 20 and the amplified data is scrambled in the data scramble block 22. The MUX 23 multiplexes the scrambled data to each input/output line according to a data width and the data output buffer block 24 transmits the data transmitted through the input/output line to an external circuit.

As described above, when the data is written in the memory cell, since the data is scrambled to have an opposite data polarity, the data scramble circuit has to be inserted in the read path. The configuration of the data scramble circuit inserted in the read path is the same with the data scramble circuit shown in FIG. 2. Also, a data scramble control signal DS-CONTROL for controlling the data scramble circuit in the read path is identical to that in the write path. However, since a column address strobe (CAS) latency is differently set according to a mode register set (MRS), the data scramble control signal DS-CONTROL has to be appropriately latched to a clock signal according to each CAS latency.

If a data width is fixed, since the multiplexer MUX is not necessary in the data input/output line, the multiplexer MUX can be removed in FIGS. 1 and 3 in accordance with another embodiment of the present invention.

Also, the data scramble circuit can be inserted at an output terminal of the write driver or inside of the write driver in the write path. Further more, in the read path, the data scramble circuit can be inserted in the sense amplification block, so that an address control can be easily carried out.

Accordingly, since the data scramble circuit is embedded in the semiconductor memory device, there are advantages that it is not necessary to reprogram the data scramble equation for each semiconductor memory device and a fail analysis for old analysis equipment, in which the data scramble is not supported, can be carried out, so that there is an effect that a cost is reduced.

While the present invention has been described with respect to the particular embodiments, it will be apparent to those skilled in the art that various changes and modifications may be made without departing from the spirit and scope of the invention as defined in the following claims.

What is claimed is:

1. A semiconductor memory device comprising:
a first data scramble circuit, which is configured between a data input buffer and a memory cell block, for outputting data by inverting or maintaining a polarity of an input data in response to a data scramble control signal; and
a second data scramble circuit, which is configured between the memory cell block and a data output buffer, for outputting data by inverting or maintaining a polarity of an output data in response to a data scramble control signal.

2. The semiconductor memory device as recited in claim 1, wherein the first and second data scramble circuits are inserted in the data input/output lines.

3. The semiconductor memory device as recited in claim 1, wherein the first data scramble circuit is inserted in a write driver.

4. The semiconductor memory device as recited in claim 1, wherein the first data scramble circuit is inserted at an output terminal of a write driver.

5. The semiconductor memory device as recited in claim 1, wherein the second scramble circuit is inserted in an input/output sense amplifier.

6. The semiconductor memory device as recited in claim 1, wherein the data scramble control signal is generated by decoding a row address signal or a column address signal.

7. The semiconductor memory device as recited in claim 6, wherein the data scramble control signal controlling the second scramble circuit is latched to a clock signal according to a column address strobe (CAS) latency.

8. The semiconductor memory device as recited in claim 6, wherein the first scramble circuit includes:
a first transfer gate for transferring input data in response to the data scramble control signal;
a first inverter for inverting the input data;
a second transfer gate for transferring inverted input data in response to the data scramble control signal; and
a second inverter for inverting the data scramble control signal.

9. The semiconductor memory device as recited in claim 6, wherein the second scramble circuit includes:
a first transfer gate for transferring input data in response to the data scramble control signal;
a first inverter for inverting the input data;
a second transfer gate for transferring inverted input data in response to the data scramble control signal; and
a second inverter for inverting the data scramble control signal.
